(19) United States
(12) Patent Application Publication
(10) Pub. No.: US 2012/0104432 A1
(43) Pub. Date: May 3, 2012

(54) SEMICONDUCTOR LIGHT EMITTING DEVICE

(76) Inventors: Hyun Wook SHIM, Suwon (KR); Dong Ju Lee, Suwon (KR); Sung Tae Kim, Seoul (KR)

(21) Appl. No.: 13/223,902

(22) Filed: Sep. 1, 2011

(30) Foreign Application Priority Data
Oct. 28, 2010 (KR) 10-2010-0105868

(51) Int. Cl. H01L 33/42

(52) U.S. Cl. 257/94; 257/E33.064

(57) ABSTRACT

A semiconductor light emitting device includes: a semiconductor light emission stacked body including a first conductive semiconductor layer, a second conductive semiconductor layer, and an active layer positioned between the first and second conductive semiconductor layers; and a highly conductive transparent electrode formed on at least one of the first and second conductive semiconductor layers and including a transparent electrode layer formed of at least one of a transparent conductive oxide layer and a transparent conductive nitride and a graphene layer allowing light within the visible spectrum to be transmitted therethrough, the transparent electrode layer and the graphene layer being stacked.

### CROSS-REFERENCE TO RELATED APPLICATIONS

This application claims the priority of Korean Patent Application No. 10-2010-0105868 filed on Oct. 28, 2010, in the Korean Intellectual Property Office, the disclosure of which is incorporated herein by reference.

### BACKGROUND OF THE INVENTION

1. Field of the Invention

The present invention relates to a semiconductor light emitting device and, more particularly, to a semiconductor light emitting device having an electrode structure configured to improve the optical characteristics and electrical characteristics thereof.

2. Description of the Related Art

A semiconductor light emitting diode is an optical device for converting electrical energy into optical energy. The semiconductor light emitting device, including a compound semiconductor emitting light of a particular wavelength according to an energy band gap, is extensively used as a backlight unit for a range of various displays such as optical communications and mobile displays, a computer monitor, and the like, to various types of lighting apparatus.

In general, a semiconductor light emitting device may be required to employ a transparent electrode in an electrode structure in order to transmit light generated from an active layer to the outside. In this case, a generally used transparent electrode material, easily satisfying the conditions for light emission, though, has a limitation in that its electrical conductivity is not good. Such shortcomings in electrical characteristics lead to an increase in a driving voltage and non-uniform current spreading, potentially resulting in a degradation of overall luminous efficiency.

### SUMMARY OF THE INVENTION

An aspect of the present invention provides a semiconductor light emitting diode including a layer of material having a high level of electrical conductivity to thereby improve the electrical characteristics and luminous efficiency thereof by guaranteeing a high level of light transmission.

According to an aspect of the present invention, there is provided a semiconductor light emitting device including: a semiconductor light emission stacked body including a first conductive semiconductor layer, a second conductive semiconductor layer, and an active layer positioned between the first and second conductive semiconductor layers; and a highly conductive transparent electrode formed on at least one of the first and second conductive semiconductor layers. The highly conductive transparent electrode includes a transparent electrode layer formed of at least one of a transparent conductive oxide layer and a transparent conductive nitride layer, and a graphene layer allowing light within the visible spectrum to be transmitted therethrough. The transparent electrode layer and the graphene layer are stacked.

The transparent electrode layer may be formed on at least one of the conductive semiconductor layers, and the graphene layer may be formed on the transparent electrode layer.

The graphene layer may be formed on at least one of the conductive semiconductor layers, and the transparent electrode may be formed on the graphene layer.

The graphene layer may be interposed between the transparent electrode layers.

The transparent electrode layer and the graphene layer may be provided as a plurality of transparent electrode layers and a plurality of graphene layers, respectively, and the highly conductive transparent electrode may have a structure in which the plurality of transparent electrode layers and a plurality of graphene layers are alternately stacked.

The transparent conductive oxide layer may be made of at least one selected from the group consisting of indium oxide (In₂O₃), tin oxide (SnO₂), indium tin oxide (ITO), zinc oxide (ZnO), magnesium (MgO), cadmium oxide (CdO), magnesium zinc oxide (MgZnO), indium zinc oxide (InZnO), indium tin oxide (InSnO), copper aluminum oxide (CuAlO₂), silver oxide (Ag₂O), gallium oxide (Ga₂O₃), zinc tin oxide (ZnSnO), and zinc indium tin oxide (ZITO).

The transparent conductive nitride layer may be made of at least one selected from the group consisting of titanium nitride (TiN), chromium nitride (CrN), tungsten nitride (WN), tantalum nitride (TaN), and niobium nitride (NbN).

The semiconductor light emission stacked body may be formed of an AlₓIn_{y}Ga_{(1-x-y)}AlN layer (0≦x≦1, 0≦y≦1, 0≦x+y≦1).

The semiconductor light emitting device may further include: an ohmic-contact layer formed between the transparent electrode layer and the at least one semiconductor layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view of a semiconductor light emitting device according to an exemplary embodiment of the present invention;

FIG. 2A is a schematic view showing a crystal structure of graphene;

FIG. 2B is a schematic view showing an σ-orbital and a π-orbital in graphene;

FIG. 3 is a modification of a semiconductor light emitting device according to an exemplary embodiment of the present invention; and

FIGS. 4 and 5 are sectional views showing semiconductor light emitting devices according to other exemplary embodiments.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

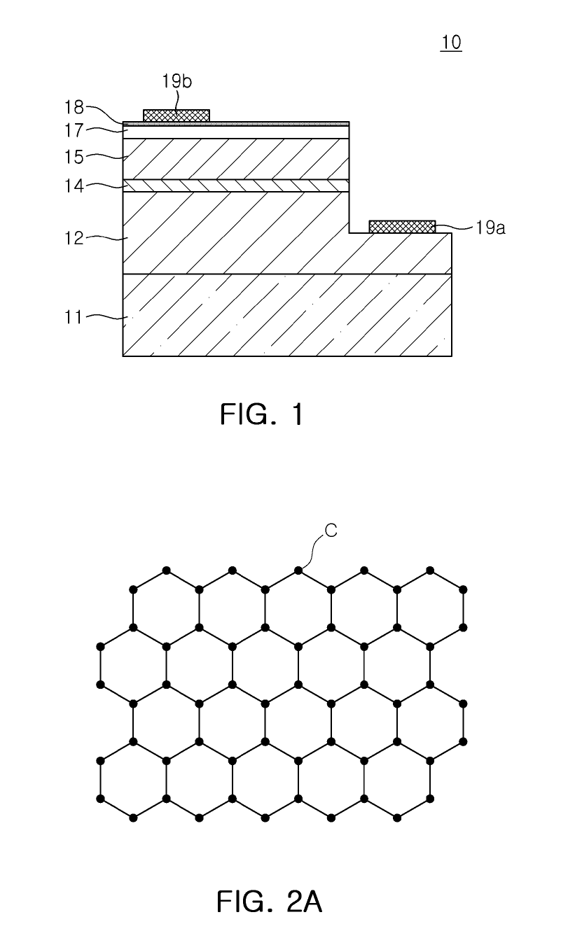

FIG. 1 is a sectional view of a semiconductor light emitting device according to an exemplary embodiment of the present invention.

As shown in FIG. 1, a semiconductor light emitting device 10 illustrated in FIG. 1 includes a substrate 11 and a semiconductor light emission stacked body including an n type semiconductor layer 12, an active layer 14, and a p type semiconductor layer 15 sequentially formed on the substrate 11.

In the present exemplary embodiment, an n-side contact metal 19a is formed on an upper surface of the n type semiconductor layer 12 which has been mesa-etched to be exposed, and a p-side contact metal 19b is formed on the p type semiconductor layer 15.

As illustrated in FIG. 1, a highly conductive transparent electrode is formed between the p-side contact metal 19b and the p type semiconductor layer 15. The highly conductive transparent electrode employed in the present exemplary embodiment may have a structure in which a transparent electrode layer 17 made of a transparent conductive oxide or a transparent conductive nitride and a graphene layer 18 formed on the transparent electrode layer 17 are stacked.

The transparent conductive oxide may be a transparent electrode layer made of indium tin oxide (ITO), but the present invention is not limited thereto and various other transparent conductive oxides may be employed. For example, the transparent conductive oxide may be at least one selected from the group consisting of indium oxide (In₂O₃), tin oxide (SnO₂), Indium tin oxide (ITO), zinc oxide (ZnO), magnesium (MgO), cadmium oxide (CdO), magnesium zinc oxide (MgZnO), indium zinc oxide (InZnO), indium tin oxide (InSnO), copper aluminum oxide(CuAlO₂), silver oxide (Ag₂O), gallium oxide (Ga₂O₃), zinc tin oxide (ZnSnO), and zinc indium tin oxide (ZITO).

When the transparent electrode layer is made of a transparent conductive nitride, the transparent conductive nitride may be at least one selected from the group consisting of titanium nitride (TiN), chromium nitride (CrN), tungsten nitride (WN), tantalum nitride (TaN), and niobium nitride (NbN).

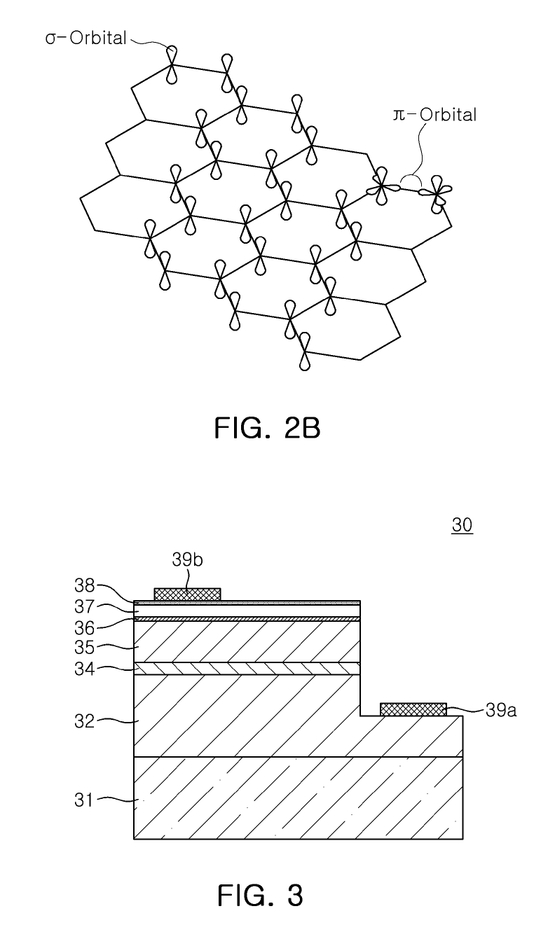

The transparent electrode layer 17 has a relatively low level of electrical conductivity, while the graphene layer can guarantee a considerably high electrical conductivity due to its unique crystal structural properties. To help understand the present invention, the graphene layer used in the present disclosure will be briefly described with reference to FIGS. 2A and 2B.

In general ‘graphene’ may be understood as an atom structure of a single layer in which carbon (C) atoms are arranged on a plane like a hexagonal honeycomb-like lattice. Carbon allotropes formed largely through covalent bonding may have numerous physical properties including a crystal structure according to a linear combination scheme of the wave function of four peripheral electrons.

In the graphene, only linear combinations of three peripheral electrons participate in strong covalent bonding between carbon atoms to form a hexagonal net-shaped plane, and the wave function of the extra peripheral electron exists in the form perpendicular to the plane.

In more detail, as shown in FIG. 2B, graphene has a σ-orbital state in which electrons are parallel to the plane and participate in the strong covalent bonding and a π-orbital state in which electrons are perpendicular to the plane, and wave functions of electrons near Fermi level determining the physical properties of graphene include linear bonds of π-orbitals.

In this manner, graphene is expected to have various characteristics based on the foregoing structural characteristics. In particular, the graphene employed in the present exemplary embodiment can advantageously provide a high level of conductivity while maintaining a light transmittance as a single carbon atom layer.

In the semiconductor light emitting device 10 illustrated in FIG. 1, the graphene layer 18 may maintain a high transmittance while having a high level of conductivity. Also, the transparent electrode 17 such as ITO has a relatively low level of electrical conductivity, so the effect of distributing current can be expected. Accordingly, an effective light emission area can be extended through the current distribution effect while improving Vf (forward voltage, i.e., operation voltage) characteristics.

The graphene layer 18 employed in the present exemplary embodiment can be directly grown from the transparent electrode layer 17. The graphene layer 18 may be grown by using a thermal chemical vapor deposition (CVD) or a metal organic chemical vapor deposition (MOCVD) process. The graphene layer 18 may be separately formed and attached or transferred to the desired transparent electrode layer 17, as necessary, rather than being directly grown on the transparent electrode layer 17.

The graphene layer 18 can implement a sufficient effect as a single atomic layer, but a plurality of graphene layers may be formed within a range through which light can be transmitted as necessary.

FIG. 3 is a modification of a semiconductor light emitting device according to an exemplary embodiment of the present invention.

A semiconductor light emitting device 30 illustrated in FIG. 3 includes a substrate 31 and a semiconductor light emission stacked body including an n type semiconductor layer 32, an active layer 34, and a p type semiconductor layer 35 sequentially formed on the substrate 31.

In the present exemplary embodiment, like the structure illustrated in FIG. 1, an n-side contact metal 39a is formed on an upper surface of the n type semiconductor layer 32 which has been mesa-etched to be exposed, and a p-side contact metal 39b is formed on the p type semiconductor layer 35.

As illustrated in FIG. 3, a highly conductive transparent electrode is formed between the p-side contact metal 39b and the p type semiconductor layer 35. Similar to the embodiment illustrated in FIG. 1, the highly conductive transparent electrode employed in the present exemplary embodiment may have a structure in which a transparent electrode layer 37 made of a transparent conductive oxide or a transparent conductive nitride and a graphene layer 38 formed on the transparent electrode layer 37 are stacked.

The semiconductor light emission stacked body employed in the present exemplary embodiment may be formed of an AlₓIn_{y}Ga_{(1-x-y)}AlN layer (0≦x≦1, 0≦y≦1, 0≦x+y≦1). For example, the n type and p type semiconductor layers 32 and 35 may be an n type GaN and a p type AlGaN/p type GaN, respectively. The active layer 35 may be an InGaN/GaN.

In this case, as shown in FIG. 3, when the transparent electrode layer 37 such as ITO cannot be in sufficient ohmic-contact with the p type semiconductor layer 35, an additional ohmic-contact layer 35 may be formed between the p type semiconductor layer 35 and the transparent electrode layer 37. Of course, the ohmic-contact layer 36 may be another graphene layer, or a different ohmic-contact layer may be used.

For example, the ohmic-contact layer 356 may be In₂O₃ including at least one selected from the group consisting of copper (Cu), zinc (Zn), and magnesium (Mg). Differently, the ohmic-contact layer 36 may be made of an alloy selected from the group consisting of MnNi, LaNi₅, ZnNi, MgNi, and ZnMg, or a metal or an alloy selected from the group consisting of rhodium (Rh), rutenium (Ru), platinum (Pt), palladium (Pd), iridium (Ir), nickel (Ni), cobalt (Co), or alloys thereof.

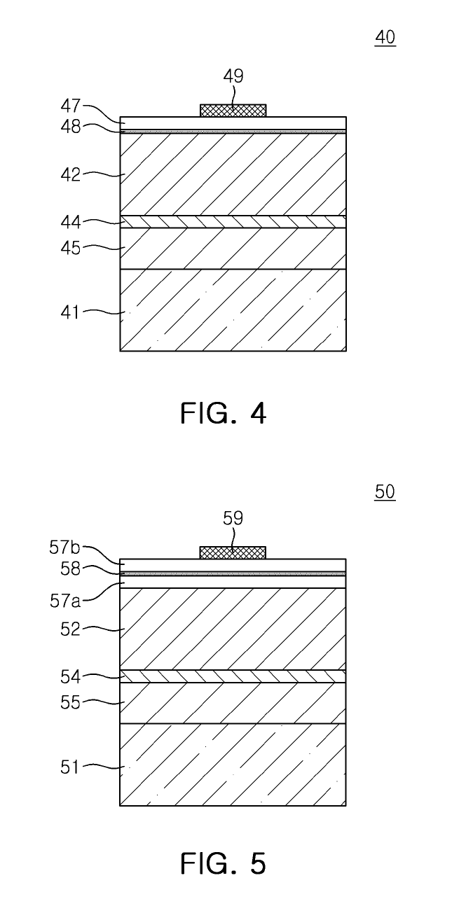

In the above embodiment, the graphene and the transparent electrode layer are employed as an electrode structure for the p type semiconductor layer, but the electrode structure may be also used for the n type semiconductor layer. Also, the highly conductive transparent electrode may be similarly applicable to semiconductor light emitting devices having various structures and variably modified and implemented. A modification of the present invention will now be described with reference to FIGS. 4 and 5.

A semiconductor light emitting device 40 illustrated in FIG. 4 includes a conductive substrate 41 and a semiconductor light emission stacked body including a second conductive semiconductor layer 45, an active layer 44, and a first conductive semiconductor layer 42 sequentially formed on the conductive substrate 41.

In the present exemplary embodiment, unlike the former exemplary embodiment, contact parts are positioned on upper and lower surface, opposed to each other, of the light emitting element. Namely, one contact metal 49 is positioned on the first conductive semiconductor layer 42, and the conductive substrate 41 serves as the other contact metal.

As shown in FIG. 4, a highly conductive transparent electrode is provided between the contact metal 49 and the first conductive semiconductor layer 42. The highly conductive transparent electrode employed in the present exemplary embodiment has a structure in which a graphene layer 48 formed on the first conductive semiconductor layer and a transparent electrode layer 47 formed on the graphene layer 48 are stacked. The transparent electrode layer 47 may be made of a transparent conductive oxide or a transparent conductive nitride.

In the present exemplary embodiment, the graphene layer 48 can allow the electrode structure and the first conductive semiconductor layer 42 to be in ohmic-contact. Also, because the transparent electrode layer 47 has a relatively low level of electrical conductivity, it can distribute current provided from the contact metal 49 having a limited area and supply the same through the graphene layer 48 providing an excellent ohmic-contact structure.

FIG. 5 shows a semiconductor light emitting device according to another exemplary embodiment of the present invention in which graphene is interposed between transparent electrode layers.

As shown in FIG. 5, the semiconductor light emitting device 50 according to the present exemplary embodiment includes a conductive substrate 51 and a semiconductor light emission stacked body including a second conductive semiconductor layer 55, an active layer 54, and a first conductive semiconductor layer 52 sequentially formed on the conductive substrate 51.

In the semiconductor light emitting device 50 illustrated in FIG. 5, similarly to the structure illustrated in FIG. 4, contact parts are positioned such that they are opposed to each other on the upper and lower surfaces of the semiconductor light emitting device 50.

Also, a highly conductive transparent electrode positioned between a contact electrode 59 and the first conductive semiconductor layer 52 includes transparent electrode layers 57a and 57b and a graphene layer 58 interposed between the transparent electrode layers 57a and 57b.

In more detail, the highly conductive transparent electrode employed in the present exemplary embodiment has a structure in which the first transparent electrode layer 57a is formed on the first conductive semiconductor layer 52, and the graphene layer 58 is formed on the first transparent electrode layer 57a, and then, the second transparent electrode layer 57b is additionally formed. Here, the first and second transparent electrode layers 57a and 57b may be made of a transparent conductive oxide or a transparent conductive nitride.

Similarly, the highly conductive electrode structure may be modified to have a structure in which a plurality of transparent electrode layers such as ITO and a plurality of graphene layers may be alternately formed.

As set forth above, according to exemplary embodiments of the invention, because a graphene layer as a layer of material having a high level of electrical conductivity is used together with a transparent electrode layer such as ITO, a high level of light transmittance as well as electrical characteristics can be guaranteed. A single graphene layer or a plurality of graphene layers may be formed within a range in which a level of light transmittance is not degraded, and because a certain current distribution effect can be expectedly obtained in the ITO layer having a slightly high electrical resistance compared with the graphene layer, an effective light emission area can be increased to enhance luminous efficiency and guarantee a high level of light transmittance.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor light emitting device comprising:
a semiconductor light emission stacked body including a first conductive semiconductor layer, a second conductive semiconductor layer, and an active layer positioned between the first and second conductive semiconductor layers; and
a highly conductive transparent electrode formed on at least one of the first and second conductive semiconductor layers, and including a transparent electrode layer formed of at least one of a transparent conductive oxide layer and a transparent conductive nitride layer and a graphene layer allowing light within the visible spectrum to be transmitted therethrough, the transparent electrode layer and the graphene layer being stacked.

2. The device of claim 1, wherein the transparent electrode layer is formed on at least one of the conductive semiconductor layers, and the graphene layer is formed on the transparent electrode layer.

3. The device of claim 1, wherein the graphene layer is formed on at least one of the conductive semiconductor layers, and the transparent electrode is formed on the graphene layer.

4. The device of claim 1, wherein the graphene layer is interposed between the transparent electrode layers.

5. The device of claim 1, wherein the transparent electrode layer and the graphene layer are provided as a plurality of transparent electrode layers and a plurality of graphene layers, respectively, and the highly conductive transparent electrode has a structure in which the plurality of transparent electrode layers and a plurality of graphene layers are alternately stacked.

6. The device of claim 1, wherein the transparent conductive oxide layer is made of at least one selected from the group consisting of indium oxide (In₂O₃), tin oxide (SnO₂), Indium tin oxide (ITO), zinc oxide (ZnO), magnesium (MgO), cadmium oxide (CdO), magnesium zinc oxide (MgZnO), indium zinc oxide (InZnO), indium tin oxide (InSnO), copper aluminum oxide (CuAlO₂), silver oxide (Ag₂O), gallium oxide (Ga₂O₃), zinc tin oxide (ZnSnO), and zinc indium tin oxide (ZITO).

7. The device of claim 1, wherein the transparent conductive nitride layer is made of at least one selected from the group consisting of titanium nitride (TiN), chromium nitride (CrN), tungsten nitride (WN), tantalum nitride (TaN), and niobium nitride (NbN).

8. The device of claim 1, wherein the semiconductor light emission stacked body is formed of an AlₓIn_{y}Ga_{(1-x-y)}AlN layer (0≦x≦1, 0≦y≦1, 0≦x+y≦1).

9. The device of claim 1, further comprising: an ohmic-contact layer formed between the transparent electrode layer and the at least one semiconductor layer.
